(19) United States
(12) Patent Application Publication
(10) Pub. No.: US 2026/0150733 A1
(43) Pub. Date: May 28, 2026

(54) ELECTRONIC COMPONENT EMBEDDED SUBSTRATE

(71) Applicant: SAMSUNG ELECTRO-MECHANICS CO., LTD., Suwon-si (KR)

(72) Inventors: Sang Won HAN, Suwon-si (KR); Tae Hong MIN, Suwon-si (KR); Jong Eun PARK, Suwon-si (KR)

(73) Assignee: SAMSUNG ELECTRO-MECHANICS CO., LTD., Suwon-si (KR)

(21) Appl. No.: 19/338,765

(22) Filed: Sep. 24, 2025

(30) Foreign Application Priority Data
Nov. 26, 2024 (KR) 10-2024-0170795

(51) Int. Cl. H01L 23/498; H01L 23/13; H01L 23/15

(52) U.S. Cl. CPC H10W 70/65; H10W 70/635; H10W 70/68; H10W 70/692

(57) ABSTRACT

An electronic component-embedded substrate includes a glass layer, a blind cavity that penetrates at least a portion of the glass layer and has a bottom surface defined by another portion of the glass layer, an electronic component at least partially disposed within the blind cavity, and an insulating material that covers at least part of the glass layer and the electronic component and fills at least part of the blind cavity. The blind cavity includes a plurality of corner areas, and each corner area has a shape that protrudes outwardly beyond a wall surface of the blind cavity in a plane. This structure reduces the risk of cracks during fabrication and improves yield and reliability.

### CROSS-REFERENCE TO RELATED APPLICATION(S)

This application claims benefit of priority to Korean Patent Application No. 10-2024-0170795 filed on Nov. 26, 2024 in the Korean Intellectual Property Office, the disclosure of which is incorporated herein by reference in its entirety.

### TECHNICAL FIELD

The present disclosure relates to an electronic component embedded substrate.

To respond to high-performance and miniaturization strategies of semiconductors, the level of miniaturization and high-density required for printed circuit boards is increasing. For example, to manufacture high-end products such as server boards, high-layer counts and large bodies are required. However, as the number of wiring layers increases and the size of the body increases, the board may become vulnerable to warpage. To prevent this problem, the use of a glass core is being considered. Meanwhile, the biggest risk in using glass cores may be cracking risk. Specifically, when processing a cavity for embedding electronic components in a glass core and disposing electronic components therein, the risk of cracks may be significant.

### SUMMARY

An aspect of the present disclosure is to provide an electronic component embedded substrate in which risk of cracking may be reduced, even when processing a blind cavity in a glass layer and disposing electronic components, thereby improving yield and reducing costs.

According to an aspect of the present disclosure, cracking issues due to contact between glass and components may be prevented by additionally processing multiple corner areas of a blind cavity when forming a blind cavity for disposing electronic components on a glass layer.

According to an aspect of the present disclosure, an electronic component embedded substrate includes a glass layer; a blind cavity penetrating at least a portion of the glass layer and having at least another portion of the glass layer as a bottom surface; an electronic component at least partially disposed within the blind cavity; and an insulating material covering at least a portion of each of the glass layer and the electronic component and filling at least a portion of the blind cavity. The blind cavity includes a plurality of corner areas, and each of the plurality of corner areas has a protruding shape protruding outwardly further than a wall surface of the blind cavity in a plane.

According to an aspect of the present disclosure, an electronic component embedded substrate includes a glass layer; a blind cavity penetrating a portion of the glass layer in a thickness direction from an upper surface of the glass layer; an electronic component at least partially disposed within the blind cavity; and an insulating material covering at least a portion of each of the glass layer and the electronic component and filling at least a portion of the blind cavity. The blind cavity includes a plurality of corner areas, and each of the plurality of corner areas at least partially extends away from a center of the blind cavity in a plan view.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a cross-sectional view schematically illustrating an example of an electronic component embedded substrate;

FIG. 3 is a cross-sectional view taken along line A-A′ of the electronic component embedded substrate of FIG. 2;

FIG. 4 is a process diagram schematically illustrating a process of forming a blind cavity having multiple corner areas protruding and/or extending in a glass layer; and

FIG. 5 is an image schematically illustrating a form of a blind cavity having multiple edge areas protruding and/or extending in a glass layer, captured using an electron microscope.

### DETAILED DESCRIPTION

Hereinafter, the present disclosure will be described with reference to the accompanying drawings. The shapes and sizes of elements in the drawings may be exaggerated or reduced for clearer description.

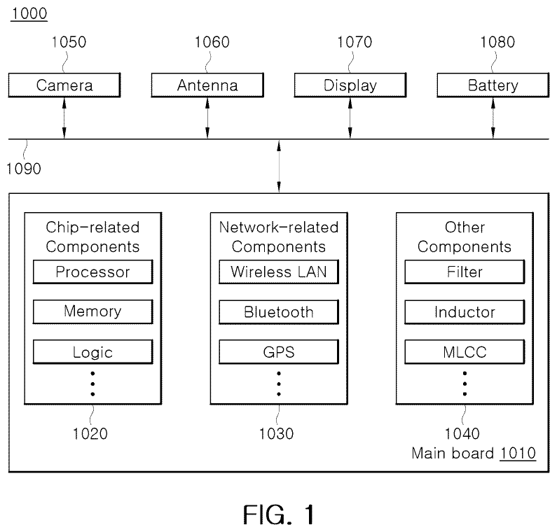

FIG. 1 is a block diagram schematically illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to other electronic components to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related electronic components. In addition, the chip related components 1020 may also be combined with each other. The chip-related component 1020 may be in the form of a package including the aforementioned chip or electronic component.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive elements in the form of chip components used for various other purposes, and the like. In addition, other components 1040 may also be combined with the chip related components 1020 and/or the network related components 1030.

Depending on a type of the electronic device 1000, the electronic device 1000 may include other electronic components that may or may not be physically or electrically connected to the mainboard 1010. These other electronic components may include, for example, a camera module 1050, an antenna module 1060, a display device 1070, a battery 1080, and the like, but are not limited thereto. These other electronic components may include an audio codec, a video codec, a power amplifier, a compass, an accelerometer, a gyroscope, a speaker, a mass storage unit (for example, a hard disk drive), a compact disc (CD) drive, a digital versatile disc (DVD) drive, or the like. In addition, these other electronic components may also include other electronic components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, a server, or the like. However, the electronic device 1000 is not limited thereto, but may be any other electronic device processing data.

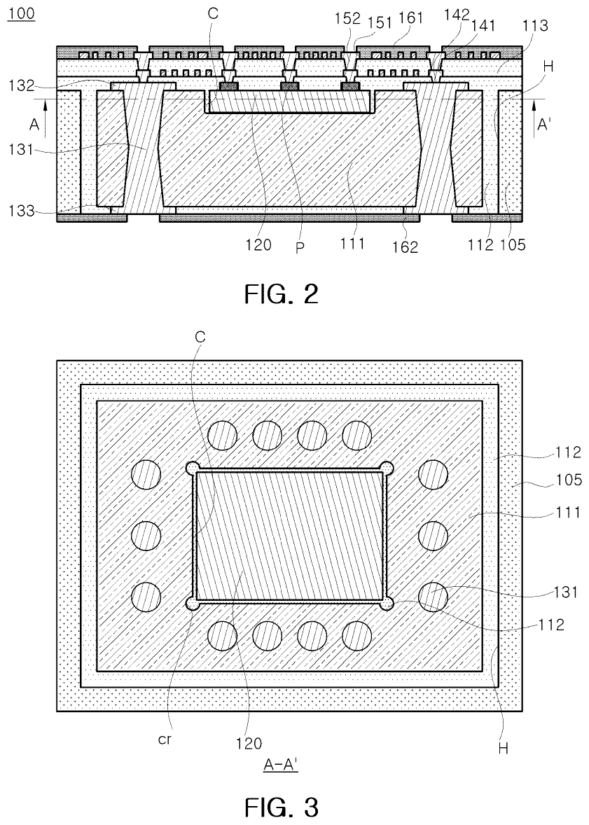

FIG. 2 is a cross-sectional view schematically illustrating an example of an electronic component embedded substrate.

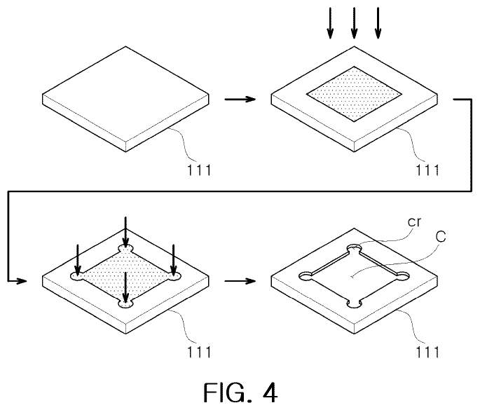

FIG. 3 is a cross-sectional view taken along line A-A′ of the electronic component embedded substrate of FIG. 2.

Referring to the drawings, an electronic component embedded substrate 100 according to an example may include a glass layer 111, a blind cavity C penetrating at least a portion of the glass layer 111 and having at least another portion thereof as a bottom surface, an electronic component 120 at least partially disposed within the blind cavity C, and an insulating material 112 covering at least a portion of each of the glass layer 111 and the electronic component 120 and filling at least a portion of the blind cavity C. The blind cavity C may penetrate one surface of the glass layer 111, for example, a portion of the glass layer 111 in the thickness direction from the upper surface of the glass layer 111. The blind cavity may include a plurality of corner areas cr. The plurality of corner areas cr may be, for example, four corner areas, but are not limited thereto, and may be some of the four corner areas. The plurality of corner areas cr may each have a shape that protrudes outwardly from the wall surface of the blind cavity C on a plane. The plurality of corner areas cr may each extend at least partly in a direction away from the center of the blind cavity C on a plane.

In this way, an electronic component embedded substrate 100 according to an example may have a blind cavity C formed in a glass layer 111, in which an electronic component 120 is to be embedded. At this time, the blind cavity C may include a plurality of corner areas cr that protrude outwardly and/or extend away from the center on a plane as described above. Therefore, when disposing an electronic component 120 in a blind cavity C, the occurrence of cracks in the glass layer 111 due to contact between the glass layer 111 and the electronic component 120 at the corner portion may be reduced. Therefore, the product manufacturing yield may be improved, the number of damaged parts may be reduced, and the manufacturing cost may be reduced.

Meanwhile, at least a portion of the protruding shape of each of the plurality of corner areas cr on the plane may be substantially circular or substantially elliptical. In addition, at least a portion of each of the plurality of corner areas cr may be extended in a substantially circular or substantially elliptical manner in a direction away from the center on the plane. For example, as in the process described below, the plurality of corner areas cr described above may be formed by additionally irradiating a laser to the plurality of respective corner portions of the blind cavity C in a substantially circular and/or elliptical shape and then removing the same by etching. Therefore, in the case of such a shape, the plurality of corner areas cr described above may be formed more easily. In addition, the crack reduction effect as described above may be enhanced through such a shape. Meanwhile, what is substantially circular or substantially elliptical may be not only a complete circle or a complete ellipse, but also an approximately circular or approximately elliptical shape, and may include a portion of the circle or a portion of the ellipse. For example, the shape thereof may have a substantially curved shape on a plane.

Meanwhile, the bottom surface of each of the plurality of corner areas cr of the blind cavity C may be disposed at substantially the same level as the bottom surface of the center area of the blind cavity C. For example, the blind cavity C may have a substantially rectangular shape in cross section. In more detail, the blind cavity C may have a substantially rectangular shape not only in a cross section in which the plurality of corner areas cr are not cut, but also in a cross section in which the plurality of corner areas cr are cut. Meanwhile, even when the blind cavity C has a substantially rectangular shape in cross section, a portion connecting the bottom surface and the wall surface of each of the center area and/or the plurality of corner areas cr of the blind cavity C may have a substantially round shape. For example, as in the process described below, the blind cavity C may be formed by first irradiating the glass layer 111 with a laser while targeting the center area thereof, additionally irradiating the glass layer 111 with a laser while targeting multiple corner areas cr thereof, and then removing the areas irradiated with the laser together by etching. Accordingly, the center area and multiple corner areas cr of the blind cavity C may be formed at substantially the same depth. In this case, multiple corner areas cr may be formed more easily, and the crack reduction effect as described above may be enhanced.

Meanwhile, the electronic component 120 may be attached to the bottom surface of the blind cavity C in a face-up form. For example, the electronic component 120 may include a connecting member P for electrical connection, and the connecting member P may be disposed on the front surface of the electronic component 120. In addition, the electronic component 120 may be attached to the bottom surface of the blind cavity C on the back surface, and at this time, a known adhesive film such as Die Attach Film (DAF) may be used. In this case, the electronic component 120 may include a plurality of corner portions, for example, four corner portions, and at least some of these corner portions may be disposed in the plurality of corner areas cr, for example, the four corner areas cr, respectively. Through this arrangement, the crack reduction effect as described above may be enhanced.

Referring to the drawings, the electronic component embedded substrate 100 according to an example may further include a metal via 131 formed on a glass layer 111, an wiring layer 141 disposed on an insulating material 112, and a via layer 142 penetrating the insulating material 112. The metal via 131 may fill at least a portion of a through-hole formed on the glass layer 111. The through-hole may penetrate the glass layer 111. For example, the through-hole may penetrate between the upper surface and the lower surface of the glass layer 111 in the thickness direction. For example, the through-hole may be a Through Glass Via (TGV). The via layer 142 may include first and second connection vias that connect the wiring layer 141 to the metal via 131 and the electronic component 120, respectively. The first connection via may be connected to the upper side of the metal via 131. The second connection via may be connected to the connecting member P of the electronic component 120. If necessary, first and second metal pads 132 and 133 may be further disposed on the glass layer 111. The first and second metal pads 132 and 133 may respectively be in contact with the metal via 131, and may be each at least partially covered by the insulating material 112. In this case, the first connection via may be connected to the metal via 131 through the first metal pad 132. However, this is not limited thereto, and the first and second metal pads 132 and 133 may be omitted. In this case, the first connection via may be directly connected to the metal via 131.

In this way, a wiring layer 141, a via layer 142, and a metal via 131 may be formed in an electronic component embedded substrate 100 according to an example, and further, the first and second metal pads 132 and 133 may be formed as needed. Accordingly, various wiring designs may be possible, and further, various electrical connection paths may be provided.

Referring to the drawings, the electronic component embedded substrate 100 according to an example may further include a frame 105 and a through-cavity H penetrating the frame 105. The through-cavity H may, for example, penetrate between the upper and lower surfaces of the frame 105 in the thickness direction. At least a portion of the glass layer 111 may be disposed within the through-cavity H. The insulating material 112 may cover at least a portion of the frame 105 and fill at least a portion of the through-cavity H. If necessary, at least a portion of the through-cavity H may be filled with a separate filler. The frame 105 may include various materials having excellent rigidity.

In this way, the electronic component embedded substrate 100 according to an example may further include the frame 105. Frame 105 may be used as a jig during the process, and thus the process may be performed at the panel level through the frame 105, and the process warpage may be easily controlled. In addition, the frame 105 may remain in the final unit after singulation, and in this case, it may be more advantageous for controlling the warpage of the final unit.

Referring to the drawing, an electronic component embedded substrate 100 according to an example may further include a build-up insulation layer 113 disposed on an insulating material 112 and covering at least a portion of an wiring layer 141, a build-up wiring layer 151 disposed on the build-up insulation layer 113, and a build-up via layer 152 disposed within the build-up insulation layer 113 and connecting the wiring layer 141 and the build-up wiring layer 151 to each other. The build-up insulation layer 113, the build-up wiring layer 151, and the build-up via layer 152 may constitute a build-up layer, and the build-up layer may be formed in multiple layers if necessary. In addition, if necessary, the build-up layer may be formed not only on the upper side but also on the lower side of the glass layer 111. If necessary, the first and second passivation layers 161 and 162 may be further disposed in the uppermost and lowermost sides of the electronic component embedded substrate 100, respectively.

In this way, the electronic component embedded substrate 100 according to an example may include the glass layer 111 as a core layer, and the build-up layer or the like may be formed on at least one side of the core layer, and thus, the electronic component embedded substrate may be easily used as a package substrate, an interposer substrate, or the like. For example, the electronic component embedded substrate 100 according to an example may be easily applied to various types of printed circuit boards and/or various forms of printed circuit boards.

Below, components of an electronic component embedded substrate 100 according to an example will be described in more detail with reference to the drawings.

The frame 105 may include an organic insulating material. The organic insulating material may include a thermosetting resin such as an epoxy resin, a thermoplastic resin such as a polyimide, or a resin together with an inorganic filler, an organic filler, and/or glass fiber (glass fiber, glass cloth, glass fabric). For example, the organic insulating material may include, but is not limited to, Copper Clad Laminate (CCL) or Unclad CCL, and may also include other organic or inorganic materials having excellent rigidity. The through-cavity H may penetrate between the upper and lower surfaces of the frame 105 in the thickness direction. The through-cavity H may continuously surround the side surface of the glass layer 111.

The glass layer 111 may include glass, which is an amorphous solid. Glass may include, for example, pure silicon dioxide (about 100% SiO₂), soda lime glass, borosilicate glass, alumino-silicate glass, or the like. However, the present disclosure is not limited thereto, and alternative glass materials such as fluorine glass, phosphate glass, chalcogen glass, or the like may also be used as materials. Additionally, other additives may be further included to form glass with specific physical properties. These additives include calcium carbonate (for example, lime) and sodium carbonate (for example, soda), as well as magnesium, calcium, manganese, aluminum, lead, boron, iron, chromium, potassium, sulfur and antimony, and carbonates and/or oxides of these elements and other elements. Meanwhile, the glass layer 111 may be distinguished from an organic insulating material including glass fiber (Glass Fiber, Glass Cloth, Glass Fabric), for example, Copper Clad Laminate (CCL), Prepreg (PPG), or the like. The glass layer 111 may be, for example, in the form of a glass plate. The blind cavity C and the plurality of corner areas cr included therein may penetrate a portion of the glass layer 111 from the upper surface of the glass layer 111 in the thickness direction. The blind cavity C and the plurality of corner areas cr included therein may continuously surround the side surface of the electronic component 120.

The insulating material 112 and the build-up insulation layer 113 may each include an organic insulating material. The organic insulating material may include a thermosetting resin such as an epoxy resin, a thermoplastic resin such as a polyimide, or a resin together with an inorganic filler, an organic filler, and/or glass fiber (glass cloth, glass fabric). For example, the organic insulating material may include, but is not limited to, Prepreg (PPG), Ajinomoto Build-up Film (ABF), Photoimageable Dielectric (PID), or the like. The insulating material 112 and the build-up insulation layer 113 may each be composed of multiple layers. The respective multiple layers may be integrated without a boundary, or the boundary between the layers may be distinguishable. The multiple layers may include substantially the same insulating material, or may include different insulating materials.

The electronic component 120 may include various types of electronic components. For example, the electronic component 120 may include various types of active components and/or passive components. For example, the electronic component may include, but is not limited to, one or more of an Integrated Circuit Device (ICD) and an Embedded Passive Integrated Component (EPIC). The electronic component 120 may include a connecting member P for electrical connection. The connecting member P may include a conductive material, for example, a metal. The metal may include copper (Cu), aluminum (Al), silver (Ag), tin (Sn), gold (Au), nickel (Ni), lead (Pb), titanium (Ti), and/or alloys thereof. The connecting member P may include an electrode or a pad, and may further include a bump or a post disposed on the electrode or the pad.

The metal via 131 and the first and second metal pads 132 and 133 may each include a metal. The metal may include copper (Cu), aluminum (Al), silver (Ag), tin (Sn), gold (Au), nickel (Ni), lead (Pb), titanium (Ti), and/or alloys thereof. For example, the metal via 131 and the first and second metal pads 132 and 133 may respectively include a titanium layer and a copper layer formed by sputtering, for example, sputtered titanium and sputtered copper, as seed layers, and may include electrolytic copper formed by electrolytic plating based on the seed layers as a pattern plating layer. The metal via 131 and the first and second metal pads 132 and 133 may respectively perform various functions depending on the design. For example, the metal via 131 may include a through-via for signal transmission, a through-via for power transmission, a through-via for ground transmission, and the like. In addition, the first and second metal pads 132 and 133 may each include a pad for signal transmission, a pad for power transmission, a pad for ground transmission, and the like. The metal via 131 may be a filled via with a metal through-hole, but may also be a conformal via with a separate filler filled therein, if necessary. The metal via 131 may have a substantially hourglass shape, but is not limited thereto, and may have, for example, a substantially cylindrical shape. The metal via 131 and the first and second metal pads 132 and 133 may each be in multiples.

The wiring layer 141 and the build-up wiring layer 151, and the via layer 142 and the build-up via layer 152 may each include a metal. The metal may include copper (Cu), aluminum (Al), silver (Ag), tin (Sn), gold (Au), nickel (Ni), lead (Pb), titanium (Ti), and/or alloys thereof. For example, the wiring layer 141 and the build-up wiring layer 151, and the via layer 142 and the build-up via layer 152 may each include chemical copper formed by electroless plating as a seed layer, and may include electrolytic copper formed by electrolytic plating based on the chemical copper as a pattern plating layer. The wiring layer 141 and the build-up wiring layer 151, and the via layer 142 and the build-up via layer 152 may respectively perform various functions depending on the design. For example, the wiring layer 141 and the build-up wiring layer 151 may include a signal pattern, a power pattern, a ground pattern, and the like, respectively. These patterns may have various shapes such as a line, a trace, a plane, a land, a pad, or the like, respectively. In addition, the via layer 142 and the build-up via layer 152 may include a connection via for signal transmission, a connection via for power transmission, a connection via for ground transmission, and the like, respectively. These connection vias may be filled vias in which a via hole is filled with metal, but may also be conformal vias in which metal is disposed along a wall surface of a via hole. The via layer 142 and the build-up via layer 152 may each include a plurality of connection vias. The connection vias included in each of the via layer 142 and the build-up via layer 152 may have a shape that is tapered in the same direction.

The first and second passivation layers 161 and 162 may each include an organic insulating material. The organic insulating material may include a thermosetting resin such as an epoxy resin, a thermoplastic resin such as a polyimide, or an inorganic filler and/or an organic filler together with the resin. For example, the organic insulating material may be Ajinomoto Build-up Film (ABF), Photoimageable Dielectric (PID), Solder Resist (SR), or the like, but is not limited thereto. The first and second passivation layers 161 and 162 may each be composed of a plurality of layers. The first and second passivation layers 161 and 162 may each have a plurality of openings, and the pattern exposed through respective openings may be a Solder Mask Defined (SMD) and/or Non Solder Mask Defined (NSMD) type, but is not limited thereto.

FIG. 4 is a process diagram schematically illustrating a process of forming a blind cavity having a plurality of corner areas protruding and/or extended in a glass layer.

Referring to the drawing, first, a glass layer 111 may be prepared. The glass layer 111 may be a glass plate as described above, but is not limited thereto. Next, a laser may be irradiated for forming a blind cavity in the glass layer 111. For example, the laser may be irradiated in an approximately quadrangular shape. Next, the laser may be additionally irradiated to each of the corners of the portion irradiated with the laser for forming the blind cavity, for example, four corners of the quadrangular shape. For example, the laser may be irradiated in an approximately circular and/or elliptical shape. Next, a portion of the glass layer 111 in the areas irradiated with the laser may be removed by etching. As a result, a blind cavity C including a plurality of corner areas cr as described above may be formed. These technical contents may be applied to the electronic component embedded substrate 100 according to the above-described example.

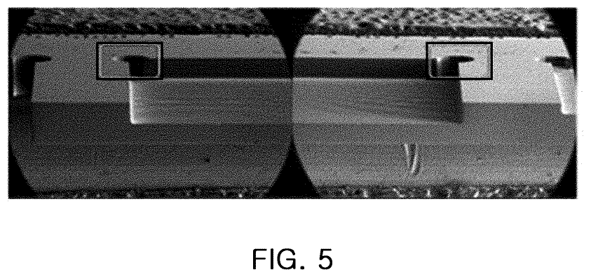

FIG. 5 is an image schematically illustrating a blind cavity having multiple edge areas protruding and/or extended on a glass layer, photographed by an electron microscope.

Referring to the drawing, a blind cavity including multiple corner areas may be formed in a glass layer through the process described above, and at this time, each of the multiple corner areas may have a hole shape of approximately circular and/or oval shape. In addition, at least a portion of the part where the wall surface of the blind cavity and the bottom surface of the blind cavity are connected may have a substantially round shape. However, the present disclosure is not limited thereto. These technical contents may be applied to the electronic component embedded substrate 100 according to the above-described example.

As set forth above, as an effect of the present disclosure, an electronic component embedded substrate may be provided in which risk of cracking may be reduced even when processing a blind cavity in a glass layer and disposing electronic components, and as a result, yield may be improved and costs may be reduced.

In the present disclosure, the expression “covering” may include not only complete covering but also partial covering, and may refer to both direct and indirect covering. In addition, the expression “filling” may include a case of filling at least partly but also a case of filling completely, and may also include a case of filling approximately. For example, it may include a case where some gaps or voids exist. Additionally, the expression of surrounding may include not only completely enclosing, but also partially enclosing and roughly enclosing. Additionally, exposing may include not only completely exposing, but also partially exposing, and exposure may mean exposing from burying the composition.

In the present disclosure, being disposed in a blind cavity or through-cavity may include not only cases where the object is disposed completely in the blind cavity or through-cavity, but also cases where it is partially extended upward or downward in the cross section. For example, if disposed in a blind cavity or through-cavity on a plane, it may be interpreted more broadly.

In the present disclosure, it may be judged to include process errors, positional deviations, measurement errors, and the like that occur in the manufacturing process. For example, being disposed at substantially the same level may include not only cases where it is disposed at completely the same level, but also cases where it is disposed at approximately the same level. In addition, having substantially a specific shape may include not only cases where it has completely such a shape, but also cases where it has approximately such a shape. In addition, substantially the same insulating material may mean not only cases where it is completely the same insulating material, but also cases where it includes the same type of insulating material. Accordingly, the composition of the insulating material may be substantially the same, but the detailed composition ratio thereof may be slightly different.

In the present disclosure, the meaning of cross-section may mean a cross-sectional shape when the object is vertically cut, or a cross-sectional shape when the object is viewed from a side-view. The meaning of a plane may mean a plane shape when the object is horizontally cut, or a plane shape when the object is viewed from a top-view or bottom-view.

In the present disclosure, lower, lower portion, lower surface, and the like are used to mean a downward direction based on the cross section of the drawing for convenience, and upper, upper portion, upper surface, and the like are used to mean the opposite direction. However, this is to define the direction for convenience of description, and the scope of the claims is not particularly limited by the description of this direction, of course, and the concept of upper and lower may change at any time.

In the present disclosure, the meaning of being connected is a concept including not only being directly connected but also being indirectly connected by an adhesive layer or the like. In addition, the meaning of being electrically connected is a concept including both physically connected and nonconnected cases. In addition, expressions such as first, second and the like are used to distinguish one component from another, and do not limit the order and/or importance of the components. In some cases, the designation of elements as “first” or “second” may be reversed without departing from the scope of the disclosure.

In the present disclosure, thickness, width, length, depth, line width, spacing, pitch, separation distance, surface roughness, and the like may be respectively measured using a scanning microscope, an optical microscope or the like based on a cross section obtained by polishing or cutting an electronic component embedded substrate. The cut section may be a vertical section or a horizontal section, and each value may be measured based on the required cut section. For example, the width of the upper end and/or the lower end of the via may be measured on a cross-section cut along the central axis of the via. At this time, if the value is not constant, the value may be determined as the average value of the values measured at five random points.

The expression “an example” used in the present disclosure does not mean the same embodiments, and is provided to emphasize and describe different unique characteristics. However, the examples presented above are not excluded from being implemented in combination with features of other examples. For example, even if a matter described in a specific example is not described in another example, it may be understood as a description related to another example, unless there is a description contrary to or contradictory to the matter in the other example.

Terms used in this disclosure are only used to describe an example, and are not intended to limit the disclosure. In this disclosure, singular expressions include plural expressions unless the context clearly indicates otherwise.

While example embodiments have been shown and described above, it will be apparent to those skilled in the art that modifications and variations could be made without departing from the scope of the present invention as defined by the appended claims.

What is claimed is:

1. An electronic component embedded substrate comprising:
a glass layer;
a blind cavity penetrating at least a portion of the glass layer and having at least another portion of the glass layer as a bottom surface;
an electronic component at least partially disposed within the blind cavity; and
an insulating material covering at least a portion of each of the glass layer and the electronic component and filling at least a portion of the blind cavity,
wherein the blind cavity includes a plurality of corner areas, and
each of the plurality of corner areas has a protruding shape extending outwardly farther than a wall surface of the blind cavity in a plane.

2. The electronic component embedded substrate of claim 1, wherein at least a portion of the protruding shape in a plane of each of the plurality of corner areas is substantially circular or substantially elliptical.

3. The electronic component embedded substrate of claim 1, wherein a bottom surface of each of the plurality of corner areas of the blind cavity is disposed at substantially the same level as a bottom surface of a center area of the blind cavity.

4. The electronic component embedded substrate of claim 3, wherein the blind cavity has a substantially rectangular shape in a cross section.

5. The electronic component embedded substrate of claim 1, wherein the plurality of corner areas comprises four corner areas spaced apart from each other.

6. The electronic component embedded substrate of claim 1, wherein the electronic component is attached to the bottom surface in a face-up orientation.

7. The electronic component embedded substrate of claim 1, wherein the electronic component has a plurality of corner portions, and at least some portions of the plurality of corner portions are respectively disposed in the plurality of corner areas.

8. The electronic component embedded substrate of claim 1, wherein the electronic component includes at least one of an Integrated Circuit Device (ICD) or an Embedded Passive Integrated Component (EPIC).

9. The electronic component embedded substrate of claim 1, further comprising:
a metal via filling at least a portion of a through-hole penetrating the glass layer;
a wiring layer disposed on the insulating material; and
a via layer penetrating the insulating material, and including a first connection via and a second connection via connecting the wiring layer to the metal via and the electronic component, respectively.

10. The electronic component embedded substrate of claim 9, further comprising a metal pad disposed on the glass layer, in contact with the metal via, and at least partially covered by the insulating material,
wherein the first connection via is connected to the metal via through the metal pad.

11. The electronic component embedded substrate of claim 9, further comprising:
a frame; and
a through-cavity penetrating the frame,
wherein the glass layer is at least partially disposed within the through-cavity, and
the insulating material covers at least a portion of the frame and fills at least a portion of the through-cavity.

12. The electronic component embedded substrate of claim 11, further comprising:
a build-up insulation layer disposed on the insulating material and covering at least a portion of the wiring layer;
a build-up wiring layer disposed on the build-up insulation layer; and
a build-up via layer disposed within the build-up insulation layer and connecting the wiring layer to the build-up wiring layer.

13. An electronic component embedded substrate comprising:
a glass layer;
a blind cavity penetrating a portion of the glass layer in a thickness direction from an upper surface of the glass layer;
an electronic component at least partially disposed within the blind cavity; and
an insulating material covering at least a portion of each of the glass layer and the electronic component and filling at least a portion of the blind cavity,
wherein the blind cavity includes a plurality of corner areas, and
each of the plurality of corner areas at least partially extends away from a center of the blind cavity in plan view.

14. The electronic component embedded substrate of claim 13, wherein at least a portion of each of the plurality of corner areas extends substantially circular or substantially oval shape in plan view.

15. The electronic component embedded substrate of claim 13, wherein the plurality of corner areas comprises four corner areas spaced apart from each other.

16. The electronic component embedded substrate of claim 13, wherein at least a portion of a region where a wall surface of the blind cavity and a bottom surface of the blind cavity are connected has a substantially round shape.

17. An electronic component embedded substrate comprising:
a glass layer;
a blind cavity penetrating at least a portion of the glass layer from an upper surface thereof in a thickness direction;
an electronic component at least partially disposed within the blind cavity;
an insulating material covering at least a portion of each of the glass layer and the electronic component and filling at least a portion of the blind cavity;
a build-up layer disposed on an upper side and a lower side of the glass layer, the build-up layer comprising:
a build-up insulation layer disposed on the insulating material and covering at least a portion of a wiring layer;
a build-up wiring layer disposed on the build-up insulation layer; and
a build-up via layer disposed within the build-up insulation layer and connecting the wiring layer and the build-up wiring layer.

18. The electronic component embedded substrate of claim 17, wherein the build-up layer is disposed on both the upper side and the lower side of the glass layer.

19. The electronic component embedded substrate of claim 17, wherein the build-up insulation layer comprises an organic insulating material including at least one of a thermosetting resin, a thermoplastic resin, an inorganic filler, an organic filler, or glass fiber.
